(19) United States
(12) Patent Application Publication
(10) Pub. No.: US 2025/0254862 A1
(43) Pub. Date: Aug. 7, 2025

(54) CONTACT FORMATION VIA A SELECTIVE ETCH

(71) Applicant: Micron Technology, Inc., Boise, ID (US)

(72) Inventors: Md. Zahid Hossain, Boise, ID (US); Surendranath C. Eruvuru, Boise, ID (US); Srinivasan Balakrishnan, Boise, ID (US); Martin W. Popp, Boise, ID (US); Lars P. Heineck, Boise, ID (US); Jin Heng Chia, Singapore (SG); Jun Rong Tan, Singapore (SG)

(21) Appl. No.: 18/789,196

(22) Filed: Jul. 30, 2024

Related U.S. Application Data
(60) Provisional application No. 63/549,334, filed on Feb. 2, 2024.

(51) Int. Cl. H10B 12/00; H01L 21/768

(52) U.S. Cl. CPC H10B 12/48; H01L 21/76805; H01L 21/76877

(57) ABSTRACT

Methods, systems, and devices for contact formation via a selective etch are described. For instance, a manufacturing system may form a first dielectric layer. Additionally, the manufacturing system may form a second dielectric layer on the first dielectric layer and a third dielectric layer on the second dielectric layer. The manufacturing system may etch the second dielectric layer and the third dielectric layer to form a set of first dielectric lines and a set of second dielectric lines. The manufacturing system may perform a metallization process to form a set of conductive lines and may form a contact above a subset of the set of conductive lines. A bottom surface of the contact may be above a respective top surface of a second dielectric line of the set of second dielectric lines based on forming the set of second dielectric lines.

### CROSS REFERENCE

The present Application for Patent claims priority to U.S. Patent Application No. 63/549,334 by Hossain et al., entitled “CONTACT FORMATION VIA A SELECTIVE ETCH,” filed Feb. 2, 2024, which is assigned to the assignee hereof, and which is expressly incorporated by reference in its entirety herein.

### TECHNICAL FIELD

The following relates to one or more systems for memory, including contact formation via a selective etch.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports contact formation via a selective etch in accordance with examples as disclosed herein.

FIGS. 2A and 2B show examples of assembly views that support contact formation via a selective etch in accordance with examples as disclosed herein.

FIGS. 3A through 3D show examples of assembly manufacturing diagrams that support contact formation via a selective etch in accordance with examples as disclosed herein.

FIGS. 4A through 4F show examples of conductive line manufacturing diagrams that support contact formation via a selective etch in accordance with examples as disclosed herein.

FIGS. 5A through 5E show examples of assembly manufacturing diagrams that support contact formation via a selective etch in accordance with examples as disclosed herein.

FIG. 6 shows a flowchart illustrating a method or methods that support contact formation via a selective etch in accordance with examples as disclosed herein.

### DETAILED DESCRIPTION

A memory device may include a set of conductive lines (e.g., word lines, digit lines) extending along a first direction. In some examples, the memory device may also include a contact coupled with one or more of the conductive lines, where the contact may be configured to connect the conductive lines with other electrical components (e.g., to enable signaling to and from page buffer circuitry). In some examples, to form the contact, a manufacturing system may form a landing pad within the set of conductive lines and may form the contact over the landing pad. Forming the landing pad may mitigate the risk that the manufacturing system punctures the set of conductive lines when forming the contact. However, forming the contact with the landing pad may involve extra manufacturing steps as compared to forming the contact without the landing pad. Thus, manufacturing the contact with the landing pad may incur additional time and cost, which may be undesirable.

In order to form the contact without the landing pad while reducing the risk that the contact punctures through the set of conductive lines, a manufacturing system may perform a selective etch when forming the contact. For instance, when etching the contact, the manufacturing system may selectively etch above a set of dielectric lines in between each of the set of conductive lines (e.g., based on a material of the set of dielectric lines). In some examples, a dielectric layer composed of a different dielectric material than the set of dielectric lines may be present above the set of dielectric lines and the set of conductive lines. In such examples, when forming the contact, the manufacturing system may etch through the dielectric layer (e.g., an oxide material) while refraining from puncturing through the set of dielectric lines (e.g., a nitride material). The manufacturing system may select etch chemistry and/or plasma characteristics to enable the manufacturing system to etch through the dielectric layer while refraining from puncturing through the set of dielectric lines. Accordingly, such manufacturing steps may reduce or otherwise mitigate the time and cost associated with manufacturing the contact.

In addition to applicability in memory systems as described herein, techniques for contact formation via a selective etch may be generally implemented to improve the sustainability of various electronic devices and systems. As the use of electronic devices has become even more widespread, the quantity of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by eliminating the material used to form the landing pad (e.g., thus reducing materials used in production of electronic devices, eliminating production processes), which may reduce electronic waste, among other benefits.

Features of the disclosure are illustrated and described in the context of systems. Features of the disclosure are further illustrated and described in the context of assembly views, assembly manufacturing diagrams, conductive line manufacturing diagrams, and flowcharts.

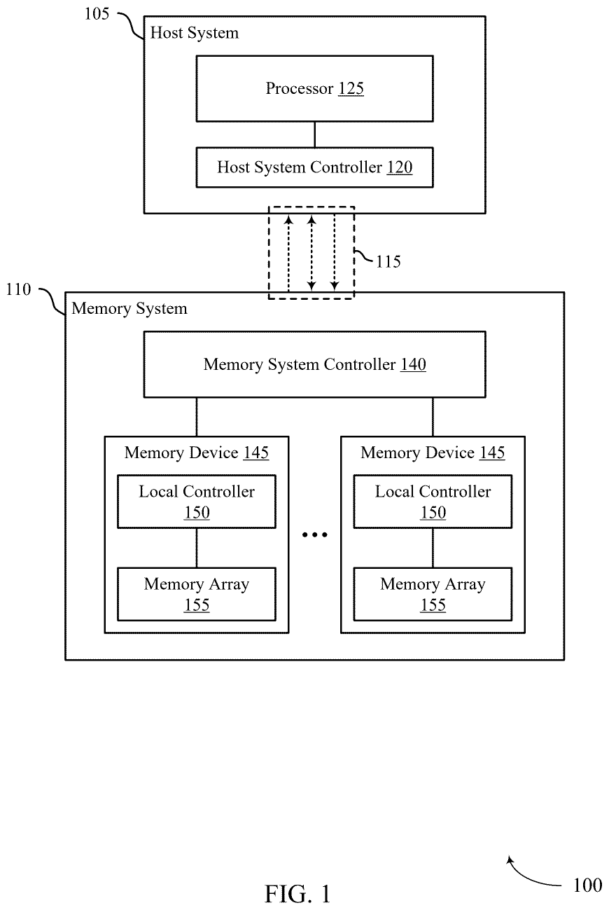

FIG. 1 illustrates an example of a system 100 that supports contact formation via a selective etch in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some example, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, a memory device 145 may include a set of conductive lines (e.g., word lines, digit lines) extending along a first direction. In some examples, the memory device 145 may also include a contact coupled with one or more conductive lines of the set of conductive lines, where the contact may be configured to connect the one or more one or more conductive lines with other electrical components (e.g., to enable signaling to and from page buffer circuitry). In some examples, to form the contact, a manufacturing system may form a landing pad within the set of conductive lines and may form the contact over the landing pad. Forming the landing pad may prevent the manufacturing system from puncturing through the set of conductive lines when forming the contact. However, forming the contact with the landing pad may involve extra manufacturing steps as compared to forming the contact without the landing pad. Thus, manufacturing the contact with the landing pad may take more time as compared to manufacturing the contact without the landing pad.

In order to form the contact without the landing pad while preventing the contact from puncturing through the set of conductive lines, a manufacturing system may perform a selective etch when forming the contact. For instance, when etching the contact, the manufacturing system may selectively etch above a set of dielectric lines in between each of the set of conductive lines (e.g., based on a material of the set of dielectric lines). In some examples, a dielectric layer composed of a different dielectric material than the set of dielectric lines may be present above the set of dielectric lines and the set of conductive lines. In such examples, when forming the contact, the manufacturing system may etch through the dielectric layer (e.g., an oxide material) while refraining from puncturing through the set of dielectric lines (e.g., a nitride material). The manufacturing system may select etch chemistry and/or plasma characteristics to enable the manufacturing system to etch through the dielectric layer while refraining from puncturing through the set of dielectric lines. Accordingly, such manufacturing steps may reduce or otherwise mitigate the time and cost associated with manufacturing the contact.

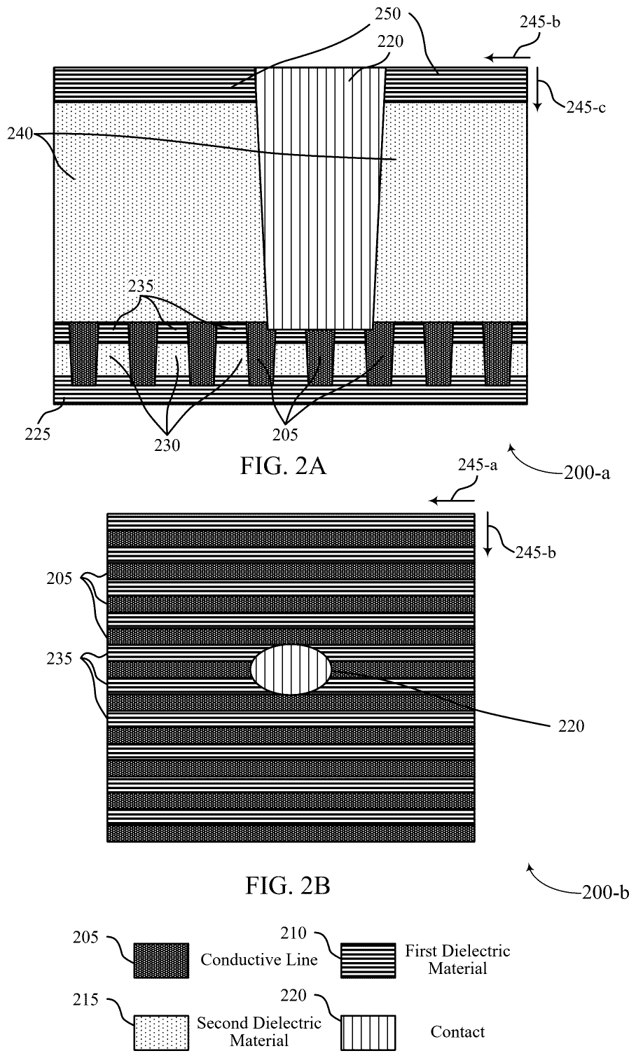

FIGS. 2A and 2B illustrates examples of assembly views 200-a and 200-b that support contact formation via a selective etch in accordance with examples as disclosed herein. For instance, FIG. 2A may depict a side cross-sectional view of an assembly and FIG. 2B may depict a top cross-sectional view of the assembly. The assembly may include a dielectric layer 225, where dielectric layer 225 includes first dielectric material 210 (e.g., a nitride material) and extending in a first direction 245-a and a second direction 245-b different from the first direction 245-a (e.g., orthogonal to first direction 245-a). The assembly may also include a set of conductive lines 205 above the dielectric layer 225 (e.g., along third direction 245-c, which may be orthogonal to first direction 245-a and second direction 245-b) and extending in the first direction 245-a. Additionally, the assembly may include a set of first dielectric lines 230 extending in the first direction 245-a and above dielectric layer 225.

The set of first dielectric lines 230 may include second dielectric material 215 (e.g., an oxide material). In some examples, each conductive line 205 of the set of conductive lines 205 may be adjacent to a respective first dielectric line 230 of the set of first dielectric lines 230 along second direction 245-b. The assembly may further include a set of second dielectric lines 235 extending in the first direction 245-a and above the set of first dielectric lines 230. The set of second dielectric lines 235 include first dielectric material 210. Each conductive line 205 of the set of conductive lines 205 may be adjacent to a respective second dielectric line 235 of the set of second dielectric lines 235. In some examples, the set of conductive lines 205 may be uniformly spaced in second direction 245-b and/or may include a tungsten material.

In some examples, the assembly may include dielectric portions 240, where each dielectric portion 240 may include second dielectric material 215. Dielectric portions 240 may be above a first subset of the set of second dielectric lines 235 and a first subset of the set of conductive lines 205. Additionally, the assembly may include dielectric portions 250, where each dielectric portion 250 may include first dielectric material 210. Dielectric portions 250 may be above the dielectric portions 240. Additionally, the assembly may include a contact 220. The contact 220 may be above a second subset of the set of second dielectric lines 235 and a second subset of the set of conductive lines 205. In some examples, a bottom surface of the contact 220 may be above (e.g., in contact with) a respective top surface of each second dielectric line 235 of the second subset of the set of second dielectric lines 235.

The assembly may lack (e.g., not include) a landing pad directly below the contact 220 (e.g., a landing pad substituting for at least some of the second dielectric lines 235, first dielectric lines 230, and conductive lines 205 below the contact 220). The landing pad may be used to reduce a risk that a manufacturing system etches through the set of conductive lines 205 when forming the contact. An assembly that lacks a landing pad may be said to be padless.

The techniques described herein may be utilized to form the contact 220 over the set of conductive lines 205 (e.g., pitch double lines, pitch quadruple lines) without a landing pad. For instance, the manufacturing system may form dielectric layer 225. Additionally, the manufacturing system may form a second dielectric layer on dielectric layer 225 and a third dielectric layer on the second dielectric layer, where each of the second dielectric layer and the third dielectric layer extend in first direction 245-a and second direction 245-b. The second dielectric layer and the third dielectric layer may each include a respective dielectric material. For instance, the second dielectric layer may include an oxide material and the third dielectric layer may include a nitride material. The manufacturing system may etch the second dielectric layer and the third dielectric layer to form the set of first dielectric lines 230 on the dielectric layer 225 and the set of second dielectric lines 235 on the set of first dielectric lines.

After forming the set of first dielectric lines 230 and the set of second dielectric lines 235, the manufacturing system may perform a metallization process to form the set of conductive lines 205. The manufacturing system may form a fourth dielectric layer including dielectric portions 240 on the set of conductive lines 205 and the set of second dielectric lines 235 and may form a fifth dielectric layer including dielectric portions 250 on the fourth dielectric layer.

The manufacturing system may selectively etch the fourth dielectric layer and the fifth dielectric layer based on set of second dielectric lines 235 including second dielectric material 215 (e.g., an oxide material). For instance, the set of second dielectric lines 235 and the set of conductive lines 205 may form a capping layer that may be used to selectively stop the contact etch process. In some cases, performing the selective etch may include forming a gap between the portions 240 of the fourth dielectric layer (e.g., a first portion 240 and a second portion 240) and the portions 250 of the fifth dielectric layer (e.g., a first portion 250 and a second portion 250), where the gap is above the second subset of the set of conductive lines 205. In some examples, the manufacturing system may form the contact 220 above the subset of the set of conductive lines 205. In such examples, forming the contact 220 may include filling the gap with the contact 220.

In some examples, the manufacturing system may form a set of resist trim lines extending in the first direction 245-a and may form the set of first dielectric lines 230 based on the set of resist trim lines. For instance, the manufacturing system may form the set of resist trim lines above the third dielectric layer and may deposit a spacer material (e.g., an oxide material) above the set of resist trim lines and the third dielectric layer. Additionally, the manufacturing system may etch the set of resist trim lines and the spacer material to form a set of spacer lines extending in the first direction 245-a and on the set of second dielectric lines 235. The set of spacer lines may be maintained on the set of second dielectric lines 235 until after the metallization process, when the manufacturing system may etch the set of spacer lines (e.g., prior to forming dielectric portions 240 and/or contact 220.

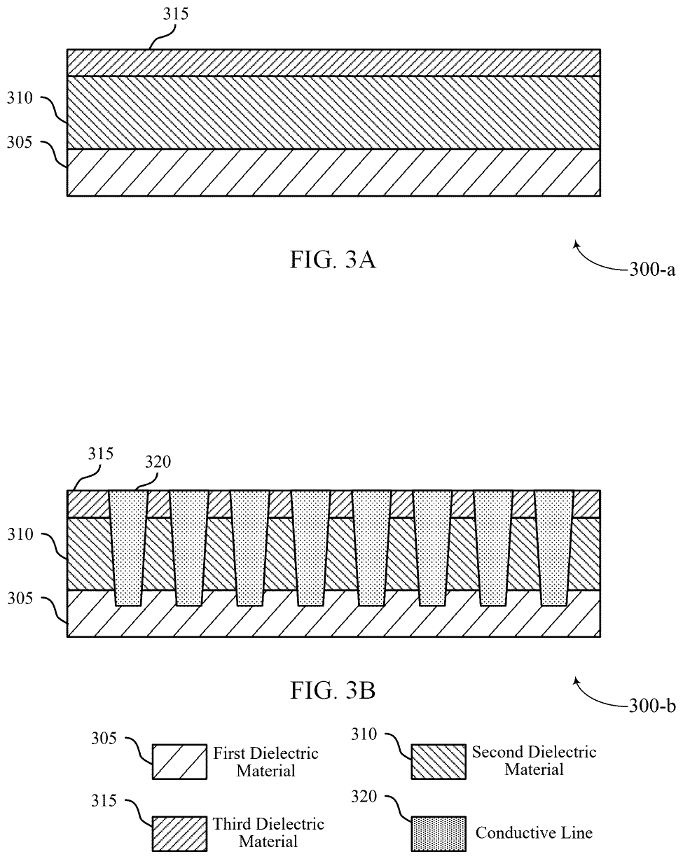

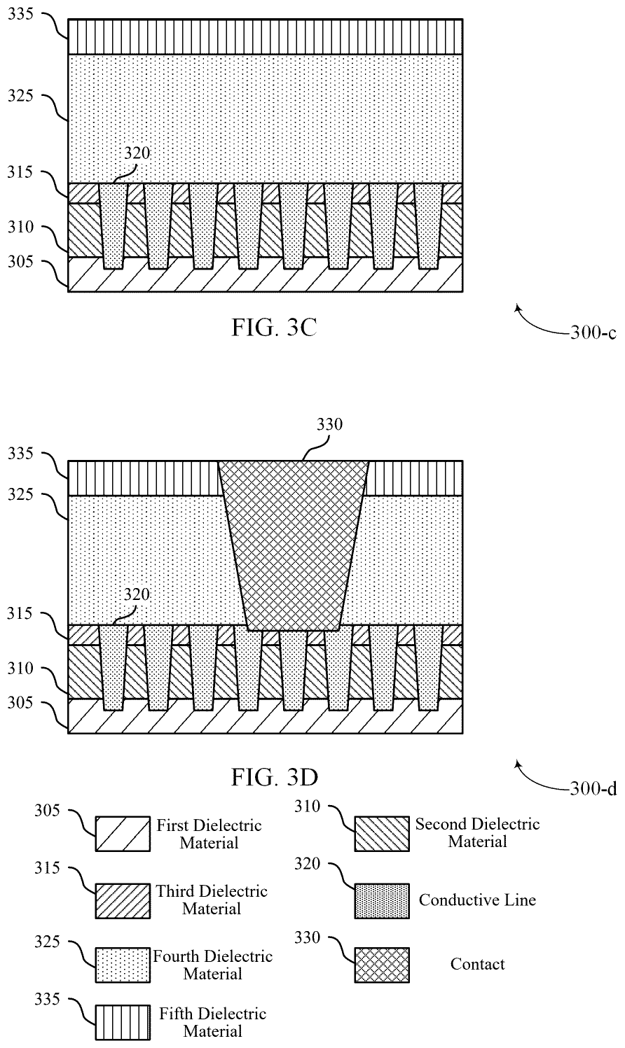

In some examples, when forming the contact 220 over the set of conductive lines 205, a manufacturing system may use selective etching to prevent the manufacturing system from punching a hole through the set of conductive lines 205. The manufacturing system may refrain from etching through the set of conductive lines 205 based on the presence of the second set of dielectric lines 235. Additionally, etching chemicals used for forming the contact 220 (e.g., or a proportion thereof) may be different than those used for forming the set of conductive lines 205. Additional details about the techniques used to form the contact 220 may be described herein, for instance, with reference to FIGS. 3A through 5E.

It should be noted that although the contact 220 is depicted as being over three conductive lines 205 of the set of conductive lines 205, a total quantity of conductive lines 205 of the set of conductive lines 205 over which contact 220 is positioned may vary. For instance, the total quantity of conductive lines 205 may be a single conductive line 205 (e.g., a conductive line whose top surface is smaller than a bottom surface of the contact 220), two conductive lines 205, four conductive lines 205, or more.

In some examples, the techniques described herein may be associated with one or more advantages. For instance, forming the contact 220 without the landing pad may reduce a total number of steps that a manufacturing system uses to form the contact 220 on the set of conductive lines 205, thus improving a cycle time used to form the contact 220 and/or otherwise simplifying the process of forming the contact 220. Additionally, removing the landing pad may allow for area shrink in examples in which the landing pad is bigger than a size of the contact 220 (e.g., in examples in which a top surface of the landing pad has a larger area than a bottom surface of the contact).

FIGS. 3A through 3D show examples of assembly manufacturing diagrams 300-a, 300-b, 300-c, and 300-d that support contact formation via a selective etch in accordance with examples as disclosed herein. In some examples, assembly manufacturing diagrams 300-a, 300-b, 300-c, and 300-d may represent steps performed to form the assembly described in FIGS. 2A and/or 2B. In such examples, first dielectric material 305 may be an example of dielectric layer 225; second dielectric material 310 may be an example of a material used to form the set of first dielectric lines 230; third dielectric material 315 may be an example of a material used to form the set of second dielectric lines 235; conductive lines 320 may be an example of conductive lines 205; fourth dielectric material 325 may an example of a material used to form portions 240; fifth dielectric material 335 may be an example of a material used to form portions 250; and contact 330 may be an example of contact 220.

As depicted in FIG. 3A, a manufacturing system may deposit a first layer that includes first dielectric material 305. Additionally, the manufacturing system may deposit a second layer on the first layer that includes second dielectric material 310 and a third layer on the second layer that includes third dielectric material 315. In some examples, first dielectric material 305 and third dielectric material 315 may each be a nitride material and second dielectric material 310 may be an oxide material. As depicted in FIG. 3B, the manufacturing system may etch the first layer, the second layer, and the third layer and may form a set of conductive lines 320. Etching the second layer and the third layer and forming the set of conductive lines 320 may form a set of first dielectric lines (e.g., first dielectric lines including the second dielectric material 310) and a set of second dielectric lines (e.g., second dielectric lines including third dielectric material 315).

As depicted in FIG. 3C, the manufacturing system may form a fourth layer on the set of conductive lines 320 and the set of second dielectric lines that includes a fourth dielectric material 325 (e.g., an oxide material) and may also form a fifth layer on the fourth layer that includes a fifth dielectric material 335 (e.g., a nitride material). As depicted in FIG. 3D, the manufacturing system may etch the fourth layer and fifth layer and may form a contact 330 in the fourth layer and fifth layer. A bottom surface of the contact 330 may be above a subset of the set of second dielectric lines and/or a subset of the set of conductive lines 320.

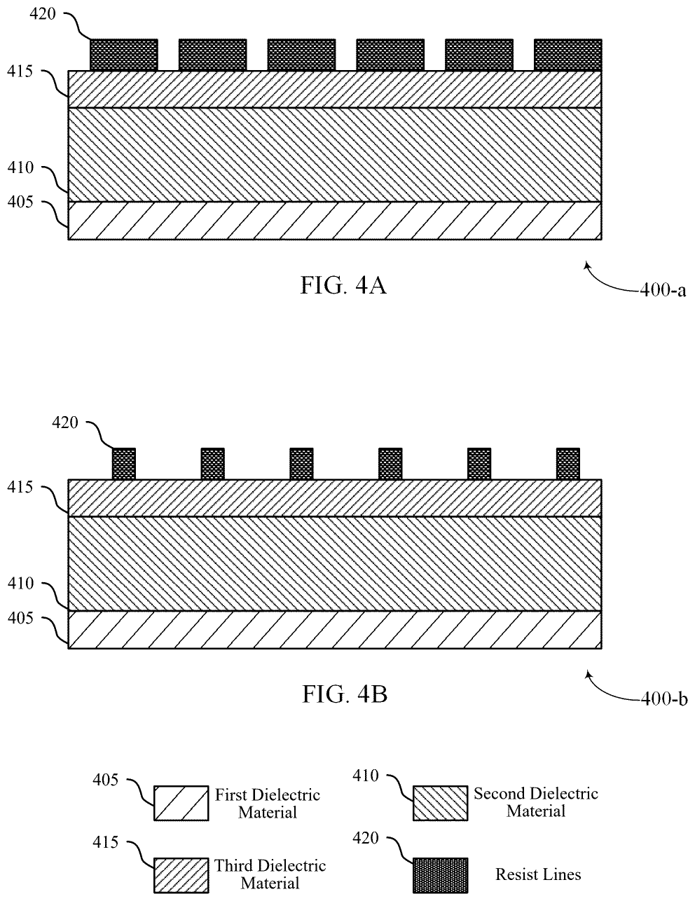

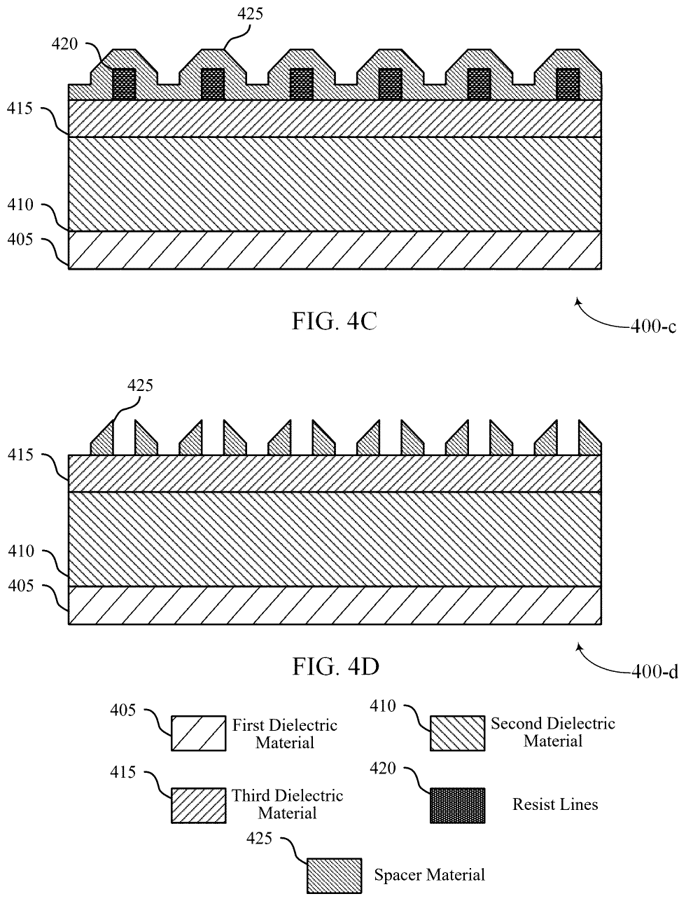

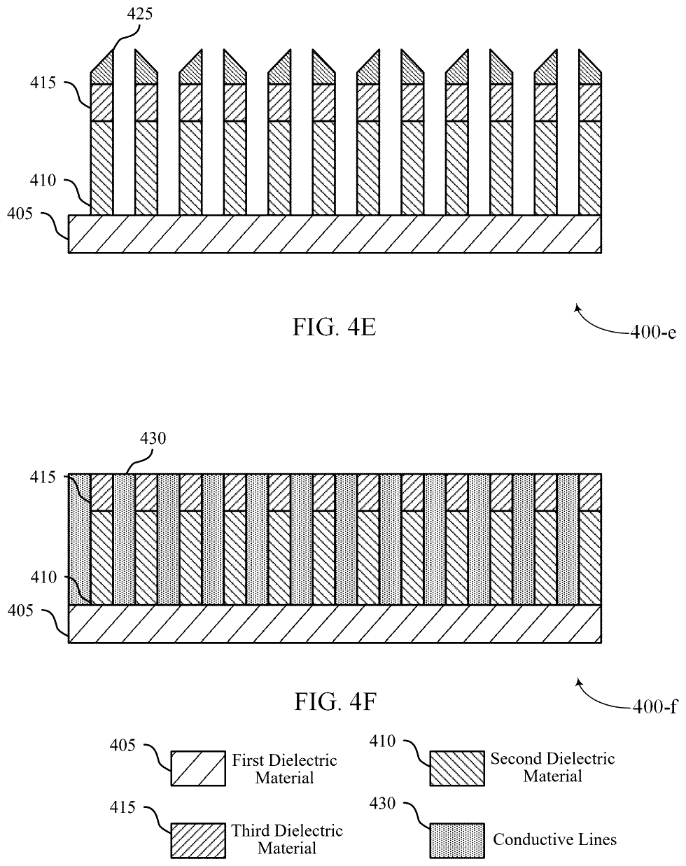

FIGS. 4A through 4F show examples of conductive line manufacturing diagrams 400-a, 400-b, 400-c, 400-d, 400-e, and 400-f that support contact formation via a selective etch in accordance with examples as disclosed herein. In some examples, conductive line manufacturing diagrams 400-a through 400-f may represent steps performed to form at least a portion of the assembly described in FIGS. 2A and/or 2B. In such examples, first dielectric material 405 may be an example of dielectric layer 225; second dielectric material 410 may be an example of a material used to form the set of first dielectric lines 230; third dielectric material 415 may be an example of a material used to form the set of second dielectric lines 235; and conductive lines 430 may be an example of conductive lines 205. Additionally, or alternatively, conductive line manufacturing diagrams 400-a through 400-f may represent steps performed as part of transitioning between assembly manufacturing diagram 300-a and assembly manufacturing diagram 300-b as depicted in FIGS. 3A and/or 3B. In such examples, first dielectric material 405 may be an example of first dielectric material 305; second dielectric material 410 may an example of second dielectric material 310; third dielectric material 415 may be an example of the third dielectric material 315; and conductive line 430 may be an example of conductive line 320.

As depicted in FIG. 4A, a manufacturing system may deposit a first layer that includes first dielectric material 405. Additionally, the manufacturing system may deposit a second layer on the first layer that includes second dielectric material 410 and a third layer on the second layer that includes third dielectric material 415. In some examples, first dielectric material 405 and third dielectric material 415 may each be a nitride material and second dielectric material 410 may be an oxide material. The manufacturing system may perform resist patterning to form a set of resist lines 420 on the third layer. As depicted in FIG. 4B, the manufacturing system may trim the set of resist lines 420 to form resist trim lines.

As depicted in FIG. 4C, the manufacturing system may deposit a spacer material 425 (e.g., an oxide material) on the set of resist trim lines and the third layer. As depicted in FIG. 4D, the manufacturing system may partially etch the spacer material 425 (e.g., may etch one or more portions of the spacer material 425, such as the portion of the spacer material 425 over the resist trim lines and one or more portions over the third layer) followed by removing (e.g., etching) the resist trim lines to form a set of spacer lines.

As depicted in FIG. 4E, the manufacturing system may etch portions of the third layer and the second layer (e.g., portions between each spacer of the set of spacers) to form a set of first dielectric lines (e.g., using material of the second layer) and a set of second dielectric lines (e.g., using material of the third layer). In some examples, the etching may be performed via a pattern transfer. As depicted in FIG. 4F, the manufacturing system may perform a metallization process to form conductive lines between each of the set of first dielectric lines and each of the set of second dielectric lines.

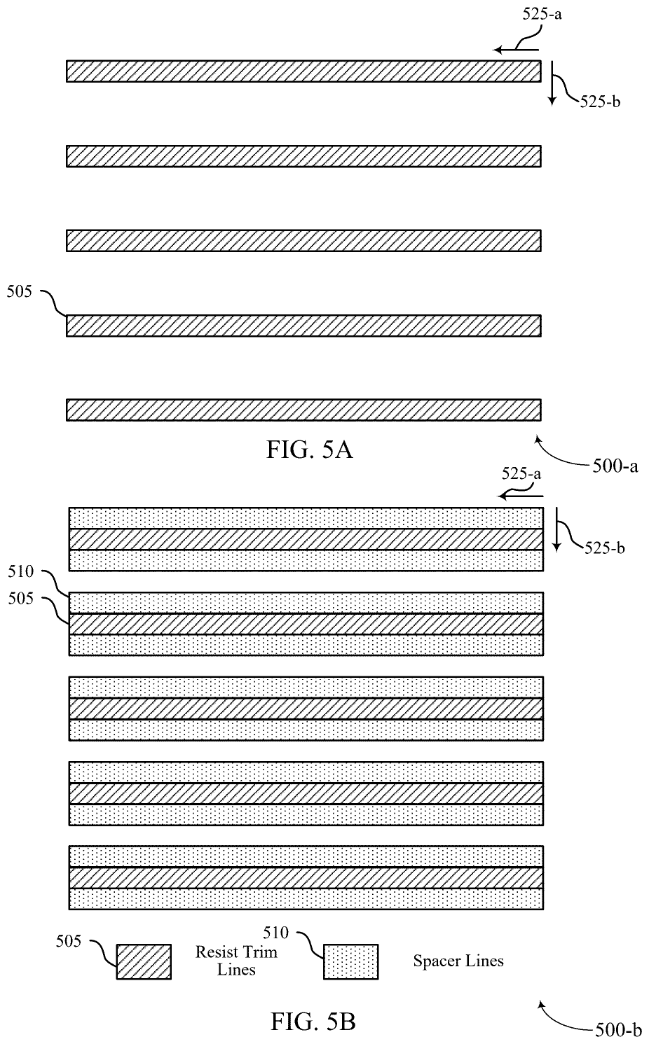

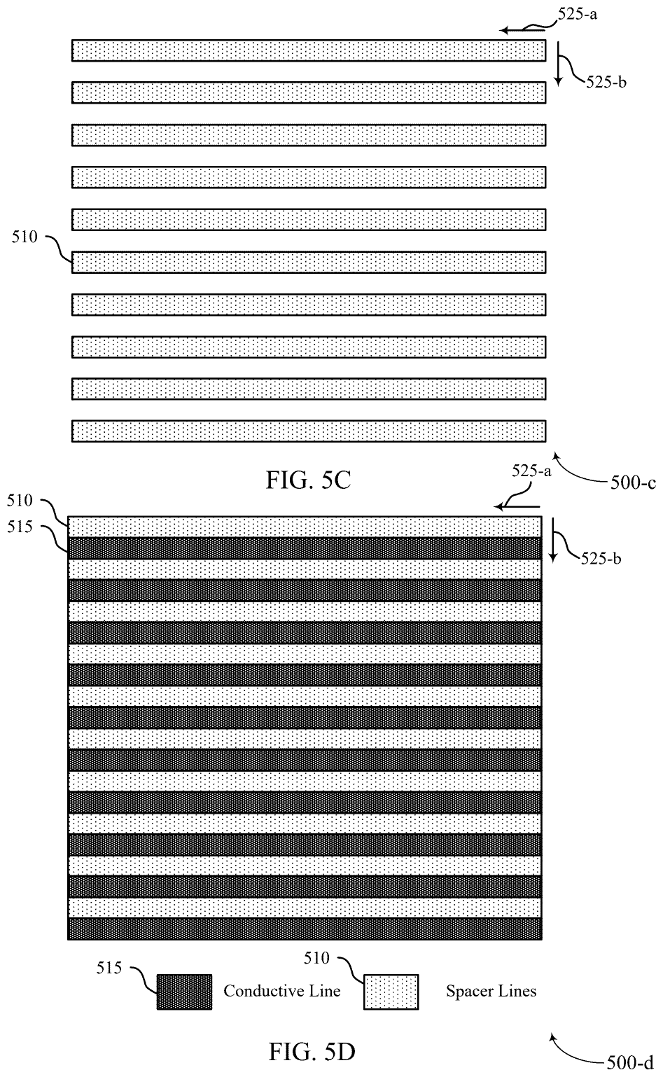

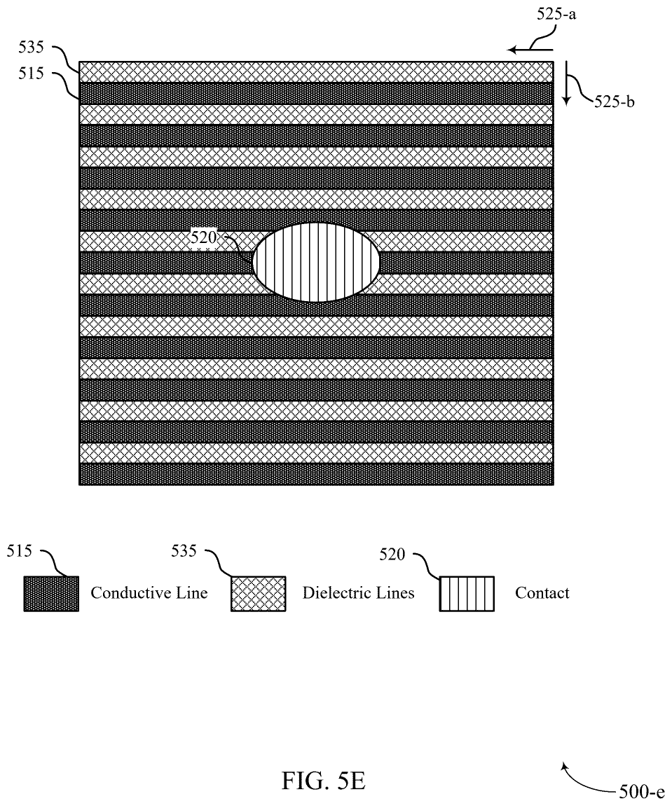

FIGS. 5A through 5E show examples of assembly manufacturing diagrams 500-a, 500-b, 500-c, 500-d, and 500-e that support contact formation via a selective etch in accordance with examples as disclosed herein. In some examples, assembly manufacturing diagrams 500-a through 500-e may represent steps performed to form at least a portion of the assembly described in FIGS. 2A, 2B, and/or 3D. In such examples, conductive lines 515 may be an example of conductive lines 205 and/or conductive lines 320; dielectric lines 535 may be an example of the set of second dielectric lines 235 and/or dielectric lines formed from the third dielectric material 315; contact 520 may be an example of contact 220 and/or contact 330 as described with reference to FIG. 3D; first direction 525-a may be an example of first direction 245-a; and second direction 525-b may be an example of second direction 245-b. Additionally, or alternatively, assembly manufacturing diagrams 500-a through 500-e may represent steps performed to form conductive lines as described with reference to FIGS. 4A through 4F. For instance, resist trim lines 505 may be an example of resist lines 420; spacer lines 510 may be an example of lines formed from spacer material 425; conductive lines 515 may be an example of conductive lines 430; and dielectric lines 535 may be an example of dielectric lines formed from second dielectric material 410.

As depicted in FIG. 5A, a manufacturing system may form a set of resist trim lines 505 extending in a first direction 525-a (e.g., as depicted in FIGS. 4A and 4B). In some examples, the set of resist trim lines 505 may be formed on a dielectric layer (e.g., dielectric layer 225 as depicted in FIG. 2A). As depicted in FIG. 5B, the manufacturing system may deposit and etch spacer lines 510 using the set of resist trim lines 505 (e.g., as depicted in FIGS. 4C and 4D). For instance, the manufacturing system may form a set of spacer lines 510 extending along first direction 525-a. The manufacturing system may form the set of spacer lines 510 on each side of the resist trim lines 505 (e.g., along second direction 525-b, which may be orthogonal to first direction 525-a).

As depicted in FIG. 5C, the manufacturing system may etch (e.g., remove) the set of resist trim lines 505. Etching the resist trim lines 505 may leave only the set of spacer lines 510, which may be uniformly spaced in at least some examples. As depicted in FIG. 5D, the manufacturing system may perform a metallization process to form a set of conductive lines 515 extending in first direction 525-a.

As depicted in FIG. 5E, the manufacturing system may etch the set of spacer lines 510 and may form a contact 520 on at least a subset of the set of conductive lines 515 and at least a subset of a set of dielectric lines 535 (e.g., dielectric lines formed from third dielectric material 415). Forming the contact 520 may include forming a second dielectric layer (e.g., an oxide layer) on the set of conductive lines 515 and the set of dielectric lines 535, where the second dielectric layer extends in first direction 525-a and second direction 525-b. Additionally forming the contact 520 may include selectively etching the second dielectric layer to form a gap between a first portion of the second dielectric layer and a second portion of the second dielectric layer and filling the gap with the contact 520. The gap may be above the subset of the set of conductive lines 515. In some examples, the selective etch may be dependent on a type of material included in the set of dielectric lines 535. For instance, the set of dielectric lines 535 may include a nitride material which may prevent the manufacturing system from punching through the set of conductive lines 515 when etching the second dielectric layer (e.g., the oxide material).

The techniques described herein may involve fewer steps than a process in which a landing pad is utilized. For instance, if using a landing pad, the techniques described herein may be modified such that after the set of resist trim lines 505 are removed as depicted in FIG. 5C, a portion of the spacer lines 510 may be etched (e.g., removed) corresponding to a location of the landing pad. Then the manufacturing system may perform a metallization process on the assembly and may form a contact. The process of etching the set of spacer lines 510 may be an extra step that the manufacturing system herein does not perform. Thus, a cycle time for forming the contact may be reduced. Additionally, the techniques described herein may enable area shrink by refraining from utilizing the landing pad.

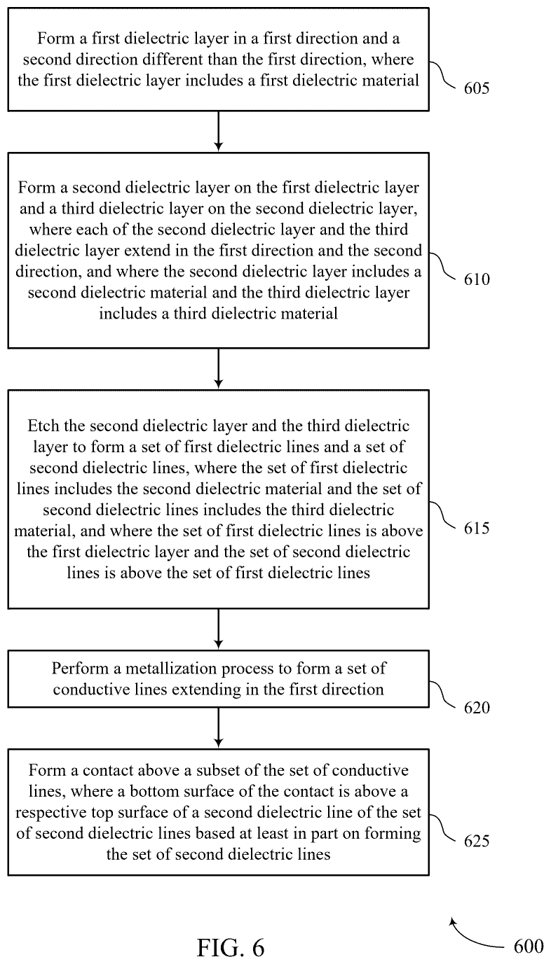

FIG. 6 shows a flowchart illustrating a method 600 that supports contact formation via a selective etch in accordance with examples as disclosed herein. The operations of method 600 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method 600 may include forming a first dielectric layer in a first direction and a second direction different than the first direction, where the first dielectric layer includes a first dielectric material. In some examples, aspects of the operations of 605 may be performed by a manufacturing system.

At 610, the method 600 may include forming a second dielectric layer on the first dielectric layer and a third dielectric layer on the second dielectric layer, where each of the second dielectric layer and the third dielectric layer extend in the first direction and the second direction, and where the second dielectric layer includes a second dielectric material and the third dielectric layer includes a third dielectric material. In some examples, aspects of the operations of 610 may be performed by a manufacturing system.

At 615, the method 600 may include etching the second dielectric layer and the third dielectric layer to form a set of first dielectric lines and a set of second dielectric lines, where the set of first dielectric lines includes the second dielectric material and the set of second dielectric lines includes the third dielectric material, and where the set of first dielectric lines is above the first dielectric layer and the set of second dielectric lines is above the set of first dielectric lines. In some examples, aspects of the operations of 615 may be performed by a manufacturing system.

At 620, the method 600 may include performing a metallization process to form a set of conductive lines extending in the first direction. In some examples, aspects of the operations of 620 may be performed by a manufacturing system.

At 625, the method 600 may include forming a contact above a subset of the set of conductive lines, where a bottom surface of the contact is above a respective top surface of a second dielectric line of the set of second dielectric lines based at least in part on forming the set of second dielectric lines. In some examples, aspects of the operations of 625 may be performed by a manufacturing system.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method, apparatus, or non-transitory computer-readable medium including operations, features, circuitry, logic, means, or instructions, or any combination thereof for forming a first dielectric layer in a first direction and a second direction different than the first direction, where the first dielectric layer includes a first dielectric material; forming a second dielectric layer on the first dielectric layer and a third dielectric layer on the second dielectric layer, where each of the second dielectric layer and the third dielectric layer extend in the first direction and the second direction, and where the second dielectric layer includes a second dielectric material and the third dielectric layer includes a third dielectric material; etching the second dielectric layer and the third dielectric layer to form a set of first dielectric lines and a set of second dielectric lines, where the set of first dielectric lines includes the second dielectric material and the set of second dielectric lines includes the third dielectric material, and where the set of first dielectric lines is above the first dielectric layer and the set of second dielectric lines is above the set of first dielectric lines; performing a metallization process to form a set of conductive lines extending in the first direction; and forming a contact above a subset of the set of conductive lines, where a bottom surface of the contact is above a respective top surface of a second dielectric line of the set of second dielectric lines based at least in part on forming the set of second dielectric lines.

Aspect 2: The method, apparatus, or non-transitory computer-readable medium of aspect 1, further including operations, features, circuitry, logic, means, or instructions, or any combination thereof for forming a fourth dielectric layer on the set of conductive lines and the third dielectric layer, where the fourth dielectric layer includes a fourth dielectric material and extends in the first direction and the second direction and selectively etching the fourth dielectric layer based at least in part on the set of second dielectric lines including the third dielectric material, where forming the contact is based at least in part on selectively etching the second dielectric layer.

Aspect 3: The method, apparatus, or non-transitory computer-readable medium of aspect 2, where selectively etching the fourth dielectric layer forms a gap between a first portion of the fourth dielectric layer and a second portion of the fourth dielectric layer; the gap is above the subset of the set of conductive lines; and forming the contact includes filling the gap with the contact.

Aspect 4: The method, apparatus, or non-transitory computer-readable medium of aspect 3, where the third dielectric material includes a nitride material and the fourth dielectric material includes an oxide material.

Aspect 5: The method, apparatus, or non-transitory computer-readable medium of any of aspects 2 through 4, where the third dielectric material and the fourth dielectric material include different dielectric materials.

Aspect 6: The method, apparatus, or non-transitory computer-readable medium of any of aspects 2 through 5, where the second dielectric material and the fourth dielectric material include a same dielectric material.

Aspect 7: The method, apparatus, or non-transitory computer-readable medium of any of aspects 1 through 6, where each conductive line of the set of conductive lines is formed adjacent to a respective first dielectric line of the set of first dielectric lines in the second direction.

Aspect 8: The method, apparatus, or non-transitory computer-readable medium of any of aspects 1 through 7, further including operations, features, circuitry, logic, means, or instructions, or any combination thereof for forming a set of resist trim lines above the third dielectric layer, the set of resist trim lines extending in the first direction; depositing a spacer material above the set of resist trim lines and the third dielectric layer; etching the set of resist trim lines and the spacer material to form a set of spacer lines extending in the first direction, where etching the second dielectric layer and the third dielectric layer is based at least in part on etching the set of resist trim lines and the spacer material; and etching the set of spacer lines after performing the metallization process.

Aspect 9: The method, apparatus, or non-transitory computer-readable medium of aspect 8, where the spacer material includes an oxide material.

Aspect 10: The method, apparatus, or non-transitory computer-readable medium of any of aspects 1 through 9, where the first dielectric material and the third dielectric material include a same dielectric material.

Aspect 11: The method, apparatus, or non-transitory computer-readable medium of any of aspects 1 through 10, where the set of conductive lines is uniformly spaced in the second direction.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 13: A memory device, including: a first dielectric layer including a first dielectric material and extending in a first direction and a second direction different than the first direction; a set of conductive lines above the first dielectric material and extending in the first direction; a set of first dielectric lines extending in the first direction and including a second dielectric material, where each conductive line of the set of conductive lines is adjacent to a respective first dielectric line of the set of first dielectric lines in the second direction; and a contact above a subset of the set of conductive lines, where a bottom surface of the contact is above a respective top surface of each first dielectric line of the set of first dielectric lines.

Aspect 14: The memory device of aspect 13, further including: a third dielectric material adjacent to the contact and on a second subset of the set of conductive lines.

Aspect 15: The memory device of aspect 14, where the first dielectric material and the second dielectric material include a same dielectric material.

Aspect 16: The memory device of any of aspect 14, where the first dielectric material and the third dielectric material include a different dielectric material.

Aspect 17: The memory device of any of aspects 13 through 16, where the second dielectric material includes a nitride material.

Aspect 18: The memory device of any of aspects 13 through 17, where the contact is above a subset of the set of first dielectric lines.

Aspect 19: The memory device of any of aspects 13 through 18, where the set of conductive lines is uniformly spaced in the second direction.

An apparatus is described. The following provides an overview of aspects of the apparatus as described herein:

Aspect 20: An apparatus, including: a first dielectric layer including a first dielectric material and extending in a first direction and a second direction different than the first direction; a set of conductive lines that are uniformly spaced on the first dielectric material and extend in the first direction; a set of first dielectric lines extending in the first direction and including a second dielectric material, where each conductive line of the set of conductive lines is adjacent to a respective first dielectric line of the set of first dielectric lines in the second direction; and a contact above a subset of the set of conductive lines, where a bottom surface of the contact is above a respective top surface of each first dielectric line of the set of first dielectric lines.

Aspect 21: The apparatus of aspect 20, further including: a third dielectric material adjacent to the contact and on a second subset of the set of conductive lines.

Aspect 22: The apparatus of aspect 21, where the first dielectric material and the second dielectric material include a same dielectric material.

Aspect 23: The apparatus of aspect 21, where the first dielectric material and the third dielectric material include a different dielectric material.

Aspect 24: The apparatus of any of aspects 20 through 23, where the second dielectric material includes a nitride material.

Aspect 25: The apparatus of any of aspects 20 through 24, where the contact is above a subset of the set of first dielectric lines.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which that can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming a first dielectric layer in a first direction and a second direction different than the first direction, wherein the first dielectric layer comprises a first dielectric material;
forming a second dielectric layer on the first dielectric layer and a third dielectric layer on the second dielectric layer, wherein each of the second dielectric layer and the third dielectric layer extend in the first direction and the second direction, and wherein the second dielectric layer comprises a second dielectric material and the third dielectric layer comprises a third dielectric material;
etching the second dielectric layer and the third dielectric layer to form a set of first dielectric lines and a set of second dielectric lines, wherein the set of first dielectric lines comprises the second dielectric material and the set of second dielectric lines comprises the third dielectric material, and wherein the set of first dielectric lines is above the first dielectric layer and the set of second dielectric lines is above the set of first dielectric lines;
performing a metallization process to form a set of conductive lines extending in the first direction; and
forming a contact above a subset of the set of conductive lines, wherein a bottom surface of the contact is above a respective top surface of a second dielectric line of the set of second dielectric lines based at least in part on forming the set of second dielectric lines.

2. The method of claim 1, further comprising:
forming a fourth dielectric layer on the set of conductive lines and the third dielectric layer, wherein the fourth dielectric layer comprises a fourth dielectric material and extends in the first direction and the second direction; and
selectively etching the fourth dielectric layer based at least in part on the set of second dielectric lines comprising the third dielectric material, wherein forming the contact is based at least in part on selectively etching the second dielectric layer.

3. The method of claim 2, wherein:
selectively etching the fourth dielectric layer forms a gap between a first portion of the fourth dielectric layer and a second portion of the fourth dielectric layer,
the gap is above the subset of the set of conductive lines, and
forming the contact comprises filling the gap with the contact.

4. The method of claim 3, wherein the third dielectric material comprises a nitride material and the fourth dielectric material comprises an oxide material.

5. The method of claim 2, wherein the third dielectric material and the fourth dielectric material comprise different dielectric materials.

6. The method of claim 2, wherein the second dielectric material and the fourth dielectric material comprise a same dielectric material.

7. The method of claim 1, wherein each conductive line of the set of conductive lines is formed adjacent to a respective first dielectric line of the set of first dielectric lines in the second direction.

8. The method of claim 1, further comprising:
forming a set of resist trim lines above the third dielectric layer, the set of resist trim lines extending in the first direction;
depositing a spacer material above the set of resist trim lines and the third dielectric layer;
etching the set of resist trim lines and the spacer material to form a set of spacer lines extending in the first direction, wherein etching the second dielectric layer and the third dielectric layer is based at least in part on etching the set of resist trim lines and the spacer material; and
etching the set of spacer lines after performing the metallization process.

9. The method of claim 8, wherein the spacer material comprises an oxide material.

10. The method of claim 1, wherein the first dielectric material and the third dielectric material comprise a same dielectric material.

11. The method of claim 1, wherein the set of conductive lines is uniformly spaced in the second direction.

12. A memory device, comprising:
a first dielectric layer comprising a first dielectric material and extending in a first direction and a second direction different than the first direction;
a set of conductive lines above the first dielectric material and extending in the first direction;
a set of first dielectric lines extending in the first direction and comprising a second dielectric material, wherein each conductive line of the set of conductive lines is adjacent to a respective first dielectric line of the set of first dielectric lines in the second direction; and
a contact above a subset of the set of conductive lines, wherein a bottom surface of the contact is above a respective top surface of each first dielectric line of the set of first dielectric lines.

13. The memory device of claim 12, further comprising:
a third dielectric material adjacent to the contact and on a second subset of the set of conductive lines.

14. The memory device of claim 13, wherein the first dielectric material and the second dielectric material comprise a same dielectric material.

15. The memory device of claim 13, wherein the first dielectric material and the third dielectric material comprise a different dielectric material.

16. The memory device of claim 12, wherein the second dielectric material comprises a nitride material.

17. The memory device of claim 12, wherein the contact is above a subset of the set of first dielectric lines.

18. The memory device of claim 12, wherein the set of conductive lines is uniformly spaced in the second direction.

19. An apparatus, comprising:
a first dielectric layer comprising a first dielectric material and extending in a first direction and a second direction different than the first direction;
a set of conductive lines that are uniformly spaced on the first dielectric material and extend in the first direction;
a set of first dielectric lines extending in the first direction and comprising a second dielectric material, wherein each conductive line of the set of conductive lines is adjacent to a respective first dielectric line of the set of first dielectric lines in the second direction; and
a contact above a subset of the set of conductive lines, wherein a bottom surface of the contact is above a respective top surface of each first dielectric line of the set of first dielectric lines.

20. The apparatus of claim 19, further comprising:
a third dielectric material adjacent to the contact and on a second subset of the set of conductive lines.

21. The apparatus of claim 20, wherein the first dielectric material and the second dielectric material comprise a same dielectric material.

22. The apparatus of claim 20, wherein the first dielectric material and the third dielectric material comprise a different dielectric material.

23. The apparatus of claim 19, wherein the second dielectric material comprises a nitride material.

24. The apparatus of claim 19, wherein the contact is above a subset of the set of first dielectric lines.

25. The apparatus of claim 19, wherein the set of conductive lines is uniformly spaced in the second direction.
